(19) United States
(12) Patent Application Publication
(10) Pub. No.: US 2011/0139241 A1
(43) Pub. Date: Jun. 16, 2011

(54) SOLAR CELL AND METHOD FOR PRODUCING A SOLAR CELL

(75) Inventors: Florian Clement, Freiburg (DE); Daniel Biro, Freiburg (DE); Michael Menko (born Lutsch), Boblingen (DE); Tim Kubera, Freiburg (DE)

(73) Assignee: FRAUNHOFER-GESELLSCHAFT ZUR FORDERUNG DER ANGEWANDTEN FORSCHUNG E.V., Munchen (DE)

(21) Appl. No.: 13/054,661

(22) PCT Filed: Jul. 10, 2009
(86) PCT No.: PCT/EP2009/005040

§ 371 Date: Feb. 3, 2011

(30) Foreign Application Priority Data
Jul. 17, 2008 (DE) 10 2008 033 632.7

(51) Int. Cl. H01L 31/0224; H01L 31/18

(52) U.S. Cl. 136/256; 438/98; 257/E31.124

(57) ABSTRACT

A solar cell and to a method for producing a solar cell is provided. The solar cell includes a semi-conductor substrate with doped regions (2a, 2b). Contact structures (3b, 3c) which are connected to the doped regions (2a, 2b) and connecting structures (4a, 4b) which are superimposed are arranged on one side of the semi-conductor substrate. The connecting structures (4a, 4b) are connected to the contact structures (3b, 3c) through openings (9) in an intermediate insulating layer (5).

### BACKGROUND

The invention relates to a solar cell according to the invention as well as to a method for the production of a solar cell according to the invention.

Solar cells of the type involved here are also designated as one-side-contact solar cells. Such solar cells have both the positive contact and also the negative contact on one metallization side of the solar cell, so that wiring of the solar cell is realized, for example, in a solar-cell module, only on the metallization side.

This has advantages especially when the metallization side is the back side of the solar cell, because in this way shadows due to the metallization areas required for the electrical wiring are not necessarily formed on the front side of the solar cell constructed for the coupling of electromagnetic radiation and thus the efficiency of the solar cell is increased due to lower shading losses.

Typical known solar-cell structures that have two contacts on one side are the MWT solar cell (EP985233), the EWT solar cell (U.S. Pat. No. 5,468,652), the RSK solar cell (U.S. Pat. No. 5,053,058), and the PUM solar cell (J. H. Bultmann, “Interconnection Through Vias For Improved Efficiency And Easy Module Manufacturing Of Crystalline Silicon Solar Cells,” published in 2001 in Solar Energy Materials & Solar Cells 65 (2001) 339-345).

For wiring these known solar-cell structures in a module, different procedures are known. Typically, the metallization for the positive contact and the metallization for the negative contact are constructed on the back side, such that a wide metallization area is arranged on two opposite edge regions, on one side the positive contact and on the other side the negative contact for the solar cell. In this way, solar cells lying one next to the other in the solar-cell module can be connected to each other electrically by strip-like cell connectors and a desired tandem wiring or series circuit of the solar cell can be realized.

For the known solutions, it is problematic that the metallization structures on the metallization side of the solar cells must be optimized simultaneously for the solar-cell structure itself and for leading away the charge carriers and for the wiring of the solar cells in the module.

Here, however, because partially contradictory optimization conditions exist, losses typically arise in the semiconductor structure and/or in the metallization structure of the solar cell, in particular, intermediate-resistance losses that lead to a reduction of the efficiency of the solar cell.

### SUMMARY

The present invention is thus based on the objective of creating a solar cell and a method for the production of a solar cell in which, for one-side-contact solar cells, the optimization potential can be better utilized with respect to efficiency under consideration of an economical and efficient wiring of the solar cell in a solar-cell module.

This objective is met by a solar cell and a method for the production of a solar cell according to the invention.

The solar cell according to the invention comprises a semiconductor substrate with a front side and a back side, as well as a first and at least one second metallic contact structure. The semiconductor substrate has at least one first doped region of a first dopant type and at least one second doped region of a second dopant type opposite that of the first dopant type. Dopant types are here n-doping and the opposite p-doping. The regions of the first and the second dopant types are arranged at least partially bordering each other for forming a pn-junction.

Typically, the first doped region is n-doped and the second doped region is p-doped. A transposition of the dopant types, however, also lies in the scope of the invention.

Both contact structures are arranged on one metallization side of the semiconductor substrate. The metallization side is the front side or the back side of the solar cell.

The first contact structure is connected in an electrically conductive manner to the first doped region and the second contact structure is connected accordingly to the second doped region.

In the sense of the present application, the designation “connected in an electrically conductive manner” disregards those currents or recombination processes that occur at or above a pn-junction. Thus, in the sense of the present application, the two doped regions are not connected in an electrically conductive manner via the pn-junction and accordingly the first contact structure is not connected in an electrically conductive manner to the second doped region and the second contact structure is not connected in an electrically conductive manner to the first doped region.

It is further essential for the solar cell to comprise a first and at least one second electrically conductive connection structure, with both of these structures being arranged on the metallization side of the solar cell.

The first contacting structure is covered at least partially by an electrically non-conductive insulation layer and this insulation layer is covered, in turn, at least partially by the first connection structure. The second contacting structure is likewise covered at least partially by an electrically non-conductive insulation layer that is covered, in turn, by the second connection structure at least partially.

The first connection structure is connected in an electrically conductive manner to the first contact structure and the second connection structure is connected in an electrically conductive way to the second contact structure.

One essential difference with the known solar-cell structures consists in that the solar cell according to the invention has, on the metallization side, a layer system that has, in a first layer, the two contact structures, an intermediate insulation layer, and arranged above these layers, the two connection structures. The insulation layer does not cover the metallization side of the solar cell over the entire surface, so that on the parts not covered by the insulation layer, an electrical connection is produced between the contact structure and the connection structure.

Advantageously, the insulation layer is constructed as a layer with recesses. Likewise, it also lies in the scope of the invention to arrange several insulation layers on the metallization side of the solar cell, so that the contact between the connection structure and the contact structure is realized between the boundaries of the insulation layers and/or the insulation layers have recesses for connecting the contact structure and connection structure.

The insulation layer (that is optionally made from several insulation layers arranged one next to the other) and the first and the second connection structures are thus integral components of the solar cell.

In this way, the solar cell according to the invention differs from known solar-cell structures in which a metallic wiring structure is part of a solar-cell module, i.e., covers the surface area of a plurality of solar cells and individual solar cells are deposited onto this component of the solar-cell module.

The solar cell according to the invention has, in contrast, on its metallization side, the layer structure described above, contact structure/insulation layer/connection structure, as an integral component.

Advantageously, the insulation layer and the first and the second connection structures do not extend significantly beyond the dimensions of the solar cell in their dimensions parallel to the metallization side, in particular, the insulation layer and the first and the second connection structures thus span a surface area that equals a maximum of 1.5 times the surface area of the metallization side, advantageously is less than or equal to the surface area of the metallization side.

In one advantageous embodiment, the contacting structures are covered essentially completely with the insulation layer up to hole-like recesses of the insulation layer. In the hole-like recesses, the connection structures border directly on correspondingly allocated contacting structures for forming an electrically conductive connection.

In another advantageous embodiment, the connection structures are constructed such that they have cross-sectional surfaces increasing and decreasing in opposite directions parallel to the metallization side. Starting from a first edge region of the solar cell, the cross-sectional surface of the first connection structure decreases toward a second edge region of the solar cell opposite the first edge region, while the cross-sectional surface of the second connection structure increases starting from the first edge region to the second edge region.

In particular, it is advantageous when the change to the cross-sectional surface exhibits a linear increase or decrease with the distance from the edge region.

Advantageously, the edge regions are constructed such that they are suitable for the application of a known cell connector. In this advantageous embodiment, it is thus possible to combine the solar cell according to the invention with already known wiring methods to form a solar-cell module.

One essential advantage of the solar-cell structure according to the invention is here that the arrangement and construction of the connection structures can be selected independent of the arrangement and construction of the contact structures. Thus, the contact structure can be optimized with respect to the arrangement and construction of the doped regions of the solar cell and independent of this, the connection structure can be optimized for the most loss-free possible leading away of charge carriers to contacting points, such as, for example, the edge regions noted above. In this way, relative to the previously known solar-cell structures, a further reduction of intermediate-resistance losses, in particular, can be achieved, so that the efficiency of the solar cell is increased.

In another advantageous construction, at least one contact structure has at least one solder pad and this contact structure is covered with the insulation layer such that the insulation layer has a recess in the region of the solder pad, so that the allocated connection structure borders directly on the solder pad. In this way, a simple and durable, electrically conductive connection can be produced between the connection structure and contact structure.

In another advantageous construction, the solar cell has the structural basic construction of a known MWT solar cell, as described, for example, in EP 985233. Here, the semiconductor substrate has via metallization areas that connect the metallization side in an electrically conductive manner by use of a metallic via connection to the opposite side of the solar cell. In this way it is thus possible to lead charge carriers, for example, from the front side of the solar cell using the via metallization to the back side of the solar cell constructed as the metallization side and to lead the carriers away there using a first contact structure bordering on the via metallization and using the allocated connection structure.

Advantageously, in this way the first contact structure is covered with the insulation layer such that the insulation layer has a recess in the region in which the via connection borders on the contact structure.

In this way, a direct leading away of the charge carriers from the via connection is guaranteed with only minimal intermediate-resistance losses.

Advantageously, for the advantageous construction of the solar cell according to the invention with the basic construction of an MWT solar cell, the first contact structure is realized together with the via metallization such that, in one processing step, starting from the metallization side, the first contact structure is generated and simultaneously the holes for the via metallization areas are filled with the material of the first contact structure.

The invention further comprises a method for the production of a solar cell according to the invention.

The method according to the invention comprises a processing step A in which a first and at least one second metallic contact structure are deposited on a metallization side of a semiconductor substrate. The semiconductor substrate has at least one first doped region of a first dopant type as described above and at least one second doped region of a second dopant type opposite that of the first dopant type. The first and the second dopant types border each other at least partially for forming a pn-junction.

In one processing step B of the method according to the invention, an electrically conductive connection of the first contact structure with the first doped region and the second contact structure with the second doped region are generated.

It is essential that, on the first contact structure, an electrically non-conductive insulation layer is deposited that covers the first contact structure at least partially and, on this insulation layer, an electrically conductive first connection structure is deposited that covers, in turn, the insulation layer at least partially. Likewise, on the second contact structure, an electrically non-conductive insulation layer is deposited that covers the second contact structure at least partially and on this insulation layer an electrically conductive second connection structure is deposited that covers, in turn, this insulation layer at least partially.

The first connection structure is connected in an electrically conductive manner to the first contact structure and the second connection structure is connected in an electrically conductive manner to the second contact structure.

Advantageously, the insulation layer and the first and the second connection structures do not extend in their dimensions significantly beyond the dimensions of the solar cell.

In one advantageous construction of the method according to the invention, the method comprises a processing step i) in which a perforated insulation layer is deposited on the metallization side of the solar cell. The insulation layer covers the first and the second contact structures and is deposited such that at least one perforation is located in the region of the first contact structure and at least one second perforation is located in the region of the second contact structure.

In one processing step ii), the first and the second connection structures are deposited on the insulation layer such that the connection structures penetrate through the insulation layer in the region of the perforations and border directly on the contacting structures.

With the present invention, it is thus possible for the first time to optimize the contact structure with respect to the construction of the semiconductor substrate due to a layer structure arranged on the metallization side of the solar cell and to simultaneously optimize the connection structure with respect to leading away the charge carriers to the contacting points with an external current circuit, in particular, within a solar-cell module.

Advantageously, the insulation layer and/or the connection structure is deposited by a known screen-printing method or by vacuum deposition.

Advantageous dimensions of the solar-cell structure according to the invention are as follows:

The solar cell advantageously has an edge length between 1 and 50 cm, in particular, an edge length between 10 cm and 20 cm is advantageous for an approximately square construction of the solar cell.

The thickness of the solar cell without the insulation layer and connection structures advantageously lies between 50 μm and 500 μm, in particular, at approximately 100 μm to 300 μm.

The metallic contact structures advantageously have a thickness of 0.1 μm to 100 μm. The insulation layer advantageously has a thickness of 1 μm to 1000 μm, in particular, a thickness between 10 μm and 100 μm. The metallic connection structures advantageously have a thickness in the range of 1 μm to 1000 μm.

Additional features and advantageous constructions of the solar cell according to the invention and the method according to the invention are explained below with reference to embodiments and the figures.

### BRIEF DESCRIPTION OF THE DRAWINGS

Here, FIGS. 1 to 5 show schematic representations of a solar cell according to the invention based on an MWT structure,

FIG. 6 show a schematic representation of the connections of two solar cells according to the invention in a solar-cell module by means of cell connectors, and

FIG. 7 shows a flowchart of a method according to the invention for the production of a solar cell according to FIGS. 1 to 5.

FIG. 8 shows a schematic representation of a solar cell according to the invention based on a back-side contact cell structure.

### DETAILED DESCRIPTION OF THE PREFERRED EMBODIMENTS

FIG. 1 shows a schematic view of the front side of the solar cell according to the invention. The solar cell according to the invention comprises a semiconductor substrate 1. This is covered on the front side over the entire surface by the first doped region that is constructed as an n-doped emitter 2a.

The front side further has a front-side contact structure 3a having several metallization fingers. These metallization fingers are connected in an electrically conductive manner to the emitter 2a, so that charge carriers from the emitter 2a can be led away from the metallization fingers of the front-side contact structure 3a.

The dashed-line circles in FIG. 1 indicate holes in the semiconductor substrate 1 that penetrate the semiconductor substrate 1 in FIG. 1 perpendicular to the plane of the drawing. In these holes, via metallization areas 7 are found that represent, for each metallization finger of the front-side contact structure 3a, an electrical connection to the back side of the solar cell according to the invention.

FIG. 2 shows a schematic representation of the back side of the solar cell according to the invention, wherein this side is the side of the solar cell designated above as the metallization side. The insulation layer and also the n-type connection and p-type connection structures are not shown in FIG. 2. The metallization side is covered in the middle by a first contact structure that is constructed as a strip-shaped back-side, n-type contact structure 3b. The contact structure 3b is arranged such that it covers those regions in which the via metallization areas 7 meet the back side of the solar cell, so that the back-side, n-type contact structure 3b is connected in an electrically conductive manner to the metallization fingers of the front-side contact structure 3a using the via metallization 7 and thus also to the emitter 2a.

The rest of the back side is essentially covered by a second contact structure that is constructed as back-side, p-type contact structures 3c.

On the contact structures 3b and 3c shown in FIG. 2, an insulation layer 5 is arranged as shown in FIG. 3. The insulation layer 5 essentially covers the entire back side of the solar cell according to the invention; the insulation layer has recesses only at individual openings 9.

The openings 9 are arranged in three rows, wherein, in FIG. 3, the uppermost and the lower row (9a and 9b) of the openings 9 extend to the contact structures 3c, while the middle row (9c) of the openings 9 in FIG. 3 extends to the contact structure 3b.

On the insulation layer shown in FIG. 3, connection structures are arranged, as shown schematically in FIG. 4, for the solar cell according to the invention.

In this way, a first connection structure is constructed as an approximately triangular, n-type connection structure 4a. This connection structure 4a is arranged such that it covers all of the openings of the middle row (9c) of the insulation layer. The n-type connection structure 4a here penetrates the openings of the middle row of the insulation layer and is thus connected in an electrically conductive manner to the back-side, n-type contact structure 3b and thus also to the emitter 2a.

A second connection structure is constructed as a p-type connection structure 4b. This connection structure 4b covers approximately the rest of the region of the back side of the solar cell according to the invention, wherein a gap that is not covered by the connection structure remains between the n-type connection structure 4a and p-type connection structure 4b, wherein this gap guarantees the electrical isolation between the connection structures 4a and 4b.

The p-type connection structure 4b covers, in particular, all of the openings 9 of the upper and the lower rows (9a and 9b) of the insulation layer 5.

Also like the n-type connection structure, the p-type connection structure 4b also penetrates the openings 9 of the insulation layer 5 covered by it and is thus connected in an electrically conductive manner to the back-side, p-type contact structures 3c and in this way likewise to the base 2b.

Advantageously, so-called “solder pads” are also deposited on the connection structures 4a and 4b. These solder pads are metallic surfaces, advantageously, approximately circular, that simplify, due to their material properties, the electrically conductive connection of the connection structures 4a and 4b to a cell connector via the solder pads.

FIG. 5 shows a section perpendicular to the plane of the drawing along the line A shown with dashed lines in FIG. 1. The semiconductor substrate 1 is covered on the front side essentially over the entire surface by the emitter 2a up to the holes in the semiconductor substrate 1 that are filled by the via metallization areas 7. Above the via metallization 7, a metallization finger of the front-side, n-type contact structure 3a is shown in longitudinal section. On the back side of the semiconductor substrate 1, the back-side, n-type contact structure 3b is arranged in the region in which the via metallization 7 meets the back side. Back-side, n-type contact structure 3b, via metallization 7, and front-side, n-type contact structure 3a border directly on each other and are connected in an electrically conductive way.

The emitter 2a extends on the hole walls along the via metallization 7 toward the back side of the semiconductor substrate 1 and covers the back side in a region that is slightly larger than the region covered by the back-side, n-type contact structure 3b.

Those regions of the semiconductor substrate 1 that are not n-doped, i.e., that are not constructed as emitter 2a, represent p-doped regions and thus form the base 2b.

The emitter 2a and base 2b border directly on each other, so that a pn-junction is formed.

On the back side of the semiconductor substrate 1, back-side, p-type contact structures 3c are arranged that are connected to the base 2b in an electrically conductive manner.

It is essential now that the contact structures 3b and 3c are covered by the insulation layer 5 that has recesses 9.

Through these recesses, the connection structures 4a and 4b arranged above the insulation layer 5 are in electrically conductive connection with the contact structures 3b and 3c.

For the solar cell according to the invention, it is thus possible to optimize the contact structures 3b and 3c, as shown, for example, in FIG. 5, to the extent that an optimal collection of charge carriers from the semiconductor substrate 1 is performed, i.e., from the emitter 2a and base 2b.

In comparison, the connection structures 4a and 4b can be optimized, as shown, for example, in FIG. 4, such that an optimum leading away of the charge carriers collected in the contact structures 3b and 3c to the edges (in FIG. 4, the right and the left edges) of the solar cell is performed.

Thus, through the solar cell according to the invention, two optimization processes can be performed independently of each other, so that, overall, the efficiency of the solar cell increases.

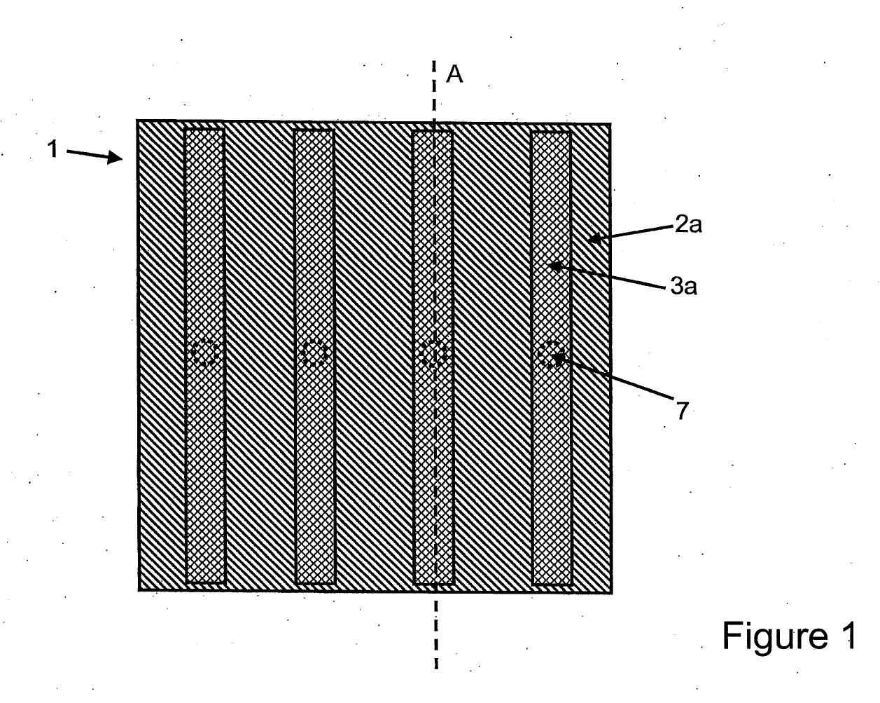

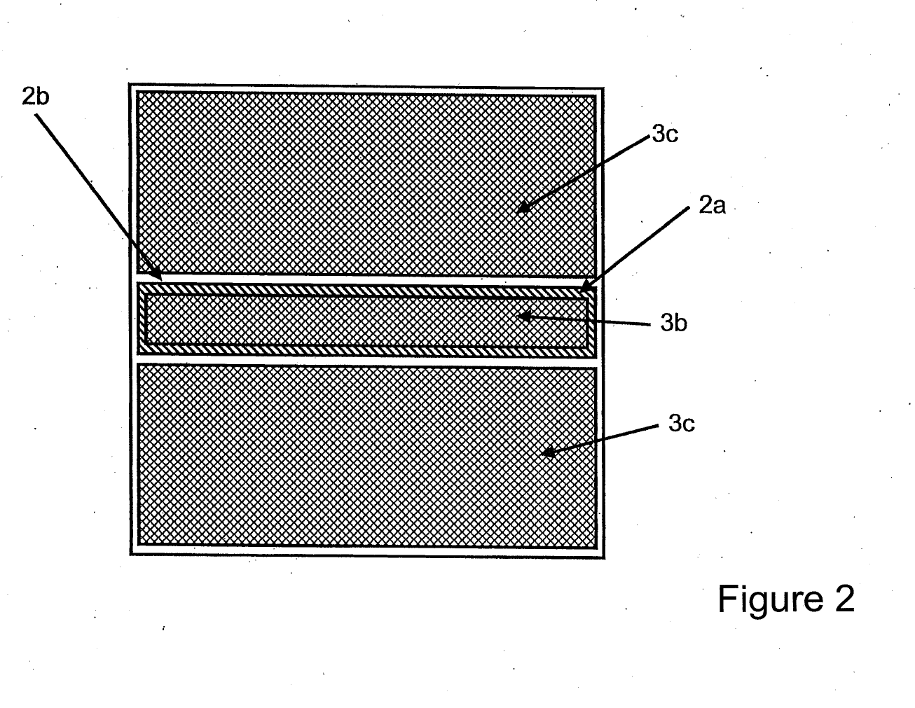

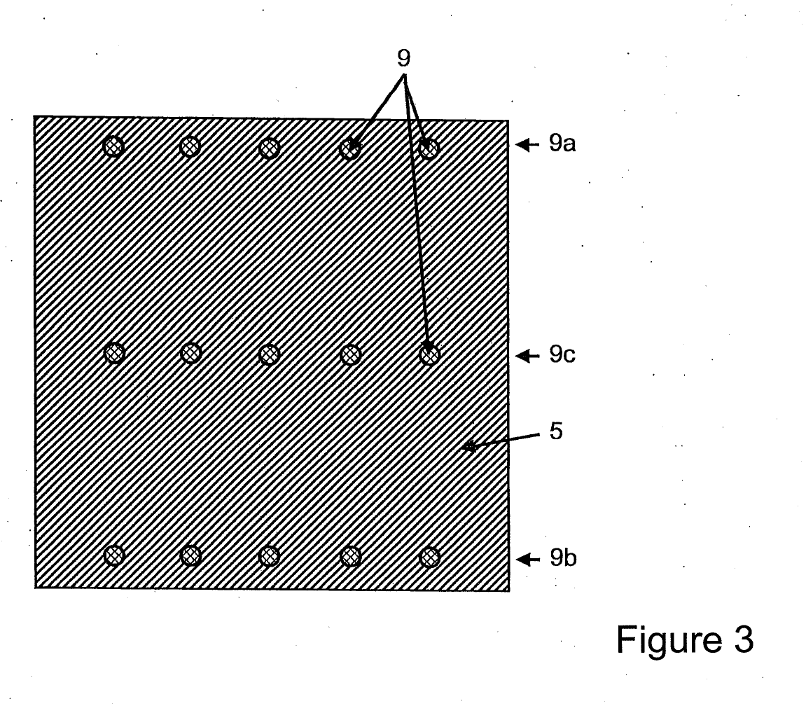

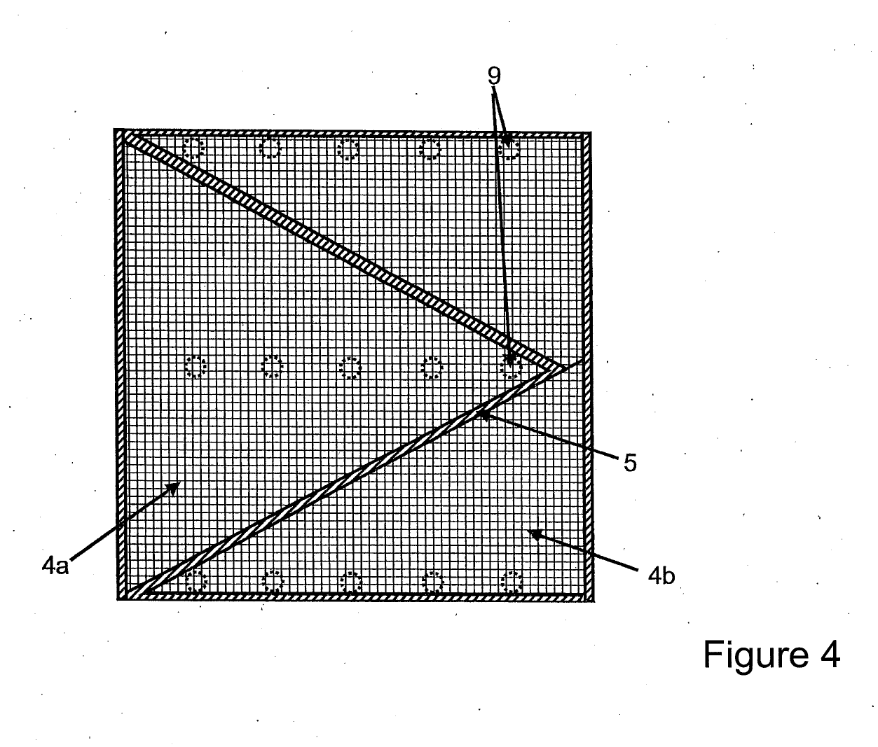

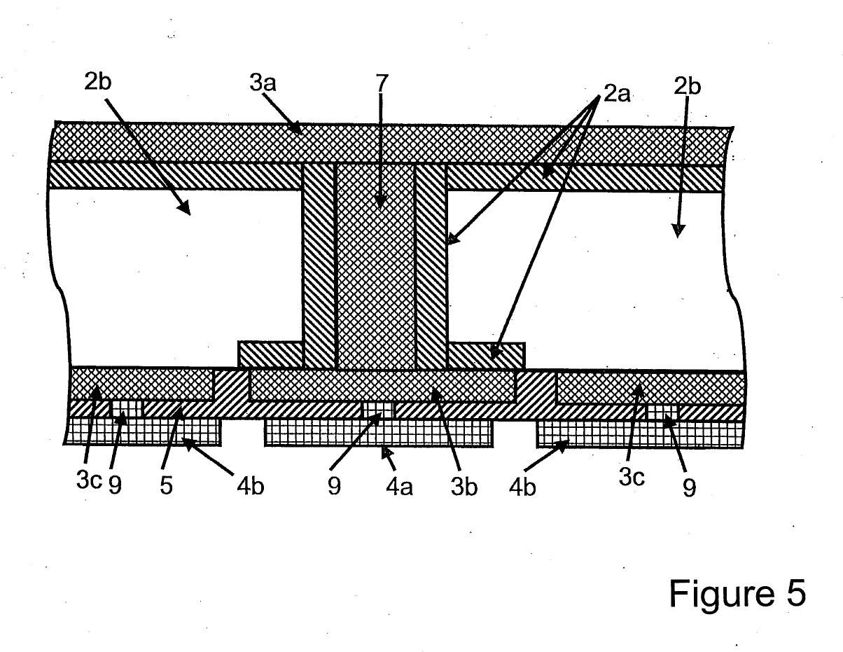

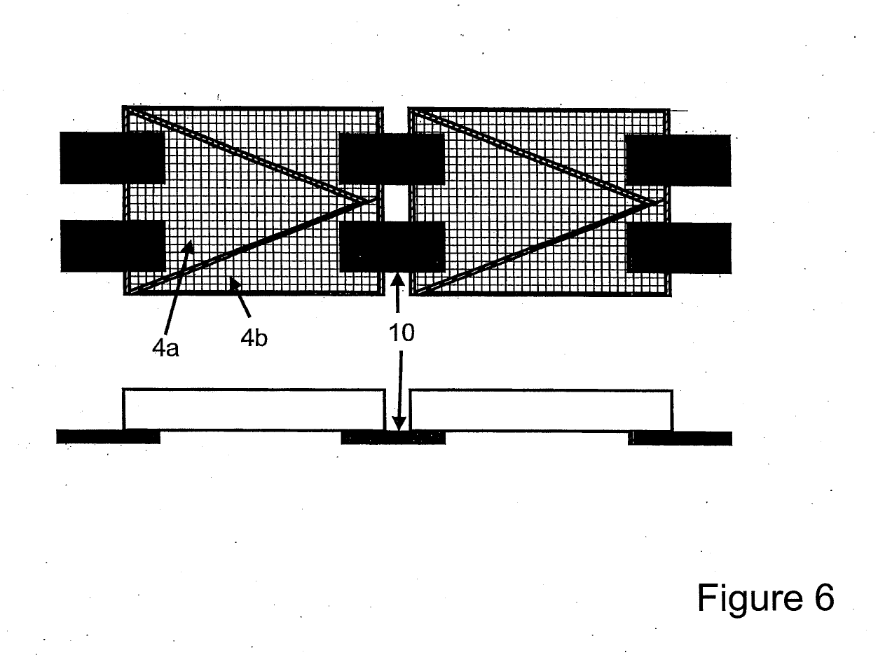

In FIG. 6, the connection of the solar cell according to the invention shown in FIGS. 1 to 5 is shown schematically in a solar-cell module. Here, in the upper region, a view from below, i.e., from the metallization side, is shown and in the lower region of FIG. 6, a side view is shown schematically in which the metallization side is arranged at the bottom.

The solar cells according to the invention are connected on the back side by cell connectors 10 such that an n-type connection structure 4a of a solar cell is connected in an electrically conductive manner via cell connector 10 to the p-type connection structure 4b of a neighboring solar cell, so that the series wiring desired in a module for solar cells is realized, in particular, via the edge region of the solar cell.

The arrangement of the cell connector shown in FIG. 6 represents a typical wiring realized in industrial solar-cell fabrication by cell connectors, so that the solar cell according to the invention can be used directly in already existing industrial fabrication processes without the need for changes. In FIG. 6, the cell connectors are shown with basic rectangular shapes. Likewise, the use of any other cell-connector shape is also conceivable, for example, cell connectors shaped like a bone are often used.

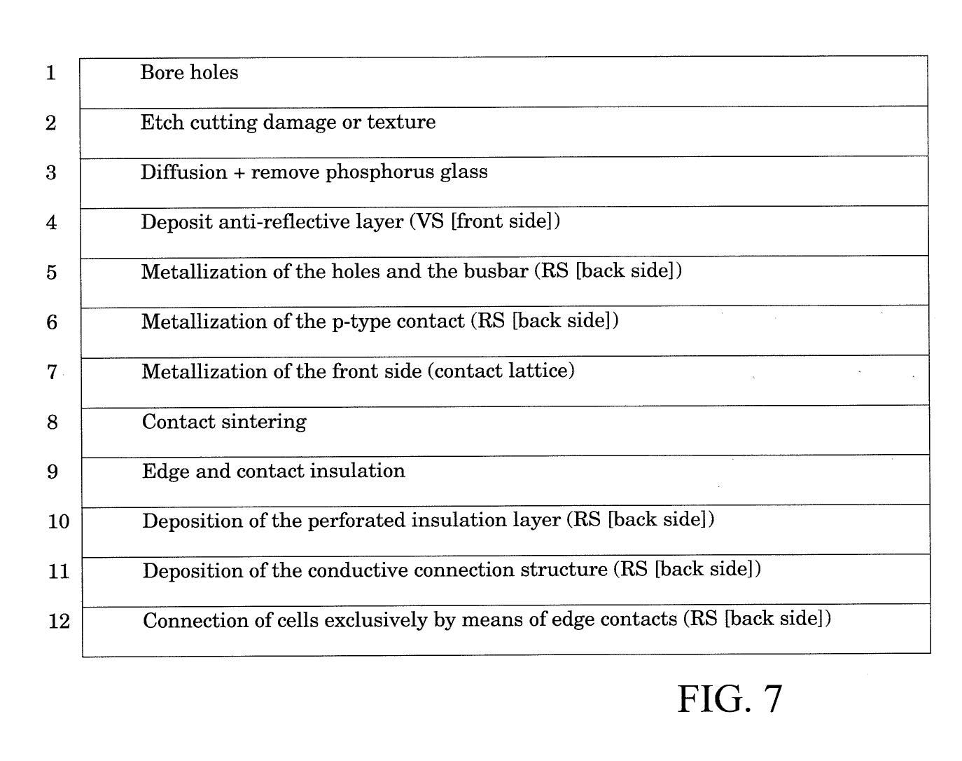

FIG. 7 represents an embodiment of the method according to the invention that is used for the production of the solar cell shown in FIGS. 1 to 6.

For this purpose, holes are first bored in a semiconductor substrate in a processing step 1. This is advantageously performed by a laser.

In a step 2, the cutting damage remaining from the production of the semiconductor substrate is removed by an etching process and optionally a texture for increasing the light coupling is deposited on the front side of the semiconductor substrate formed for the light coupling. According to the process being used and according to the field of application of the solar cell, it can also be advantageous to deposit the texture on both sides, i.e., on the front side and on the back side. In this way, the solar-cell fabrication process can be simplified and/or the light-coupling properties of the solar cell can be improved.

The semiconductor substrate has a homogeneous p-doping.

In a step 3, the diffusion of the emitter 2a that extends across the entire front side, across the hole walls, and partially across the back side is performed. The back side of the semiconductor substrate is covered as shown in FIG. 5 by the emitter 2a in the regions in which the holes are located. Typically, in step 3, the diffusion is performed on both sides (i.e., on the front side and back side) and over the entire surface.

The diffusion can be performed by known diffusion from the gas phase after deposition of a masking layer on the back side, wherein the masking layer is deposited by photolithography, or advantageously by screen-printing technology. In this case, step 9 (edge and contact isolation) is not required.

Likewise, it is also possible, however, to perform the diffusion by a known printing method of a doping paste and a subsequent temperature step, wherein the doping paste is deposited on the front side on the entire surface and on the back side only in the regions as shown in FIG. 5. In the printing method, the doping paste likewise penetrates the holes, so that the doping of the hole walls takes place simultaneously.

In a step 4, an anti-reflection layer is deposited on the front side of the semiconductor substrate, with this layer also increasing the light coupling.

In a step 5, the metallization of the via metallization areas 7, as well as the back-side, n-type contact structure 3b is performed.

In a step 6, the metallization of the p-type contact is performed, i.e., the back-side, p-type contact structure 3c is deposited using known techniques, advantageously by screen printing.

In a step 7, the metallization of the front-side contact structure 3a is realized. Also here, known metallization techniques can be used; the use of known screen-printing technology is advantageous.

With respect to steps 5, 6, and 7, other sequences of these three processing steps also lie in the scope of the invention.

In a step 8, by use of a temperature step, a so-called “contact sintering” is performed, i.e., the electrical contact is created between the deposited metallization areas and the bordering doped regions of the semiconductor substrate.

In a step 9, the edges are isolated, in order to achieve an electrical isolation of defects that often occur at the edges, such as short circuits or recombination centers. Likewise, in this step a contact insulation on the metallization side is performed. In this step, the emitter is separated electrically from the p-type contact.

Advantageously, the insulation is performed by so-called “laser isolation,” i.e., the emitter regions are removed in a linear shape using a laser, in order to achieve electrical isolation of the emitter regions on these lines.

It is essential, in a processing step 10, for the insulation layer 5 to be deposited according to FIGS. 1 to 5. The insulation layer can be deposited, for example, by screen-printing technology, such that it has the desired recesses. Likewise, it is conceivable to deposit the insulation layer initially over the entire surface and then, at the locations at which recesses are desired, to remove the insulation layer again, for example, using a laser.

In a step 11, the n-type connection structure 4a and the p-type connection structure 4b are deposited with one of the previously described methods, advantageously by screen printing or vacuum deposition.

For the module wiring, in a step 12 an electrical connection of adjacent cells is produced, in particular, via the edge region, finally by use of connectors as shown in FIG. 6.

Likewise, it lies in the scope of the invention to integrate step 5 in step 11. Thus, in this variant of the method according to the invention, in step 11, for the deposition of the n-type connection structure 4a above the openings 9, the back-side, n-type contact structure 3b and the via metallization 7 are also generated. Here, an electrically conductive contact of the via metallization 7 is generated with the front-side contact structure 3a. In this embodiment of the method according to the invention, step 5 is eliminated.

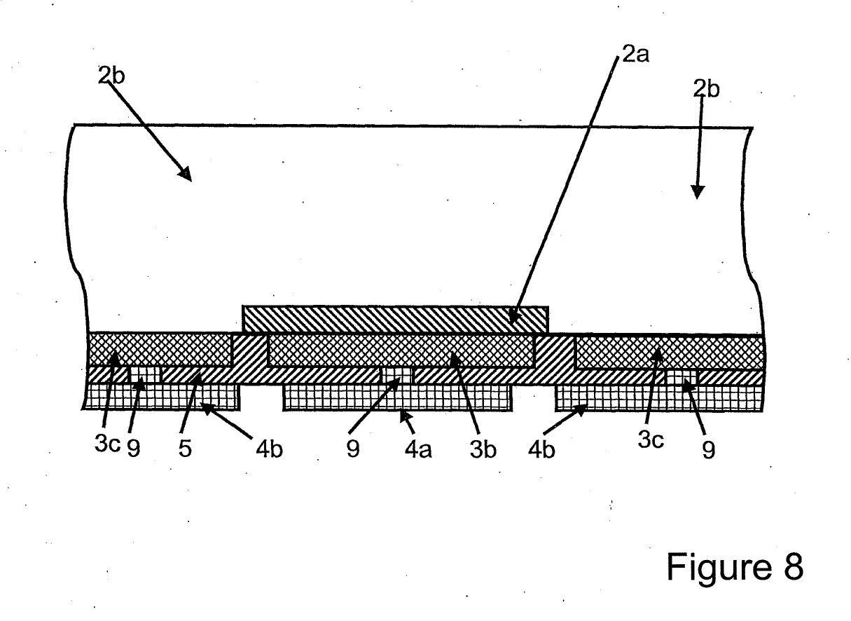

The schematic representation in FIG. 8 shows a section perpendicular to the front side of another embodiment of a solar cell according to the invention that is based on a known structure of a back-side contact cell.

The basic construction of this solar cell corresponds to the construction of the solar cell shown in FIGS. 1 to 6 and accordingly, identical reference symbols also designate identical elements. The solar-cell structure shown in FIG. 8, however, has only one emitter 2a on the back side and accordingly, the front-side contact structure 3a, the holes, and the via metallization 7 and the corresponding n-doped regions on the front side and on the hole walls are eliminated.

The structure shown in FIG. 8 is likewise produced with a method according to the invention according to FIG. 7, wherein step 1 and step 7 are eliminated.

The solar-cell structure according to FIG. 8 has the advantage that it is less complex compared with the solar-cell structure shown in FIGS. 1 to 6 and therefore can be produced with lower expense and therefore more economically. A disadvantage is that n-doped regions are located only on the back side. This can lead to a lower efficiency compared with the solar-cell structure shown in FIGS. 1 to 6.

1. Solar cell comprising
a semiconductor substrate with a front side and a back side, a first and at least one second metallic contact structure,
the semiconductor substrate has at least one first doped region of a first dopant type and at least one second doped region of a second dopant type opposite that of the first dopant type and the first and the second dopant types are arranged at least partially bordering each other for construction of a pn-junction,
both of the contact structures are arranged on one metallization side of the semiconductor substrate and the metallization side is the front side or the back side of the solar cell, and
the first contact structure is connected in an electrically conductive manner to the first doped region and the second contact structure is connected in an electrically conductive manner to the second doped region,
a first and at least one second electrically conductive connection structure, with both of the connection structures being arranged on the metallization side of the solar cell,
the first contact structure is covered at least partially by an electrically non-conductive insulation layer that is covered at least partially by the first connection structure and the second contacting structure is covered at least partially by an electrically non-conductive insulation layer that is covered at least partially by the second connection structure,
the first connection structure is connected in an electrically conductive manner to the first contact structure and the second connection structure is connected in an electrically conductive manner to the second contact structure,
and the insulation layer and the first and the second connection structures are integral components of the solar cell.

2. Solar cell according to claim 1, wherein the insulation layer and the first and the second connection structures do not extend significantly beyond dimensions of the solar cell in their dimensions parallel to the metallization side.

3. Solar cell according to claim 1, wherein the contact structures are covered essentially completely with the insulation layer up to hole-like recesses and, in the hole-like recesses, the connection structures directly border on correspondingly allocated contact structures for forming an electrically conductive connection.

4. Solar cell according to claim 1, wherein the connection structures have cross-sectional surfaces increasing and decreasing in opposite directions parallel to the metallization side, such that starting from a first edge region of the solar cell, the cross-sectional surface of the first connection structure decreases toward a second edge region of the solar cell opposite the first edge region and, in an opposite direction, the cross-sectional surface of the second connection structure increases starting from the first edge region toward the second edge region, such that, starting from the first edge region, the cross-sectional surface of the first connection structure exhibits an approximately linear decrease toward the second edge region and accordingly the cross-sectional surface of the second connection structure exhibits an approximately linear increase starting from the first edge region toward the second edge region.

5. Solar cell according to claim 4, wherein the first edge region and the second edge region are each constructed suitably for deposition of a cell connector.

6. Solar cell according to claim 1, wherein at least one of the contact structures has at least one solder pad and the contact structure is covered with an insulation layer such that the insulation layer has a recess in a region of the solder pad so that an allocated connection structure borders directly on the solder pad for forming an electrically conductive connection.

7. Solar cell according to claim 1, wherein the solar cell corresponds in its basic construction to a structure of a known MWT solar cell, wherein the semiconductor substrate has via metallization areas that connect the metallization side in an electrically conductive manner using a metallic via connection to the opposite side of the solar cell, and the first contact structure on the metallization side borders on the metallic via connection for forming an electrically conductive connection, the first contact structure is covered with the insulation layer such that the insulation layer has a recess in a region in which the via connection borders on the contact structure.

8. Solar cell according to claim 7, wherein the first contact structure and the via connection are produced in one processing step.

9. Solar cell module, comprising at least two solar cells that each have two electrical contacting regions on one metallization side, the solar cells are constructed according to claim 1, and the at least two solar cells are arranged one lying next to the other in the solar-cell module, wherein the bordering edge regions of the solar cells are connected in an electrically conductive manner by a cell connector.

10. Method for the production of a solar cell, comprising the following processing steps:
(A) deposition of a first and at least one second metallic contact structure on one metallization side of a semiconductor substrate, wherein the semiconductor substrate has at least one first doped region of a first dopant type and at least one second doped region of a second dopant type that is opposite that of the first dopant type and the first and the second dopant types are arranged at least partially bordering each other for forming a pn-junction,
(B) generation of an electrically conductive connection of the first contact structure to the first doped region and the second contact structure to the second doped region,
on the first contact structure, depositing an electrically non-conductive insulation layer that covers the first contact structure at least partially and, on the insulation layer, depositing an electrically conductive first connection structure that covers the insulation layer at least partially and likewise, on the second contact structure, depositing an electrically non-conductive insulation layer that covers the second contact structure at least partially and, on the insulation layer, depositing an electrically conductive second connection structure is deposited that covers the insulation layer at least partially,
connecting the first connection structure in an electrically conductive manner to the first contact structure and connecting the second connection structure in an electrically conductive manner to the second contact structure, and the insulation layer and the first and the second connection structures are integral components of the solar cell.

11. Method according to claim 10, wherein the insulation layer and the first and the second connection structures do not extend significantly beyond dimensions of the solar cell in their dimensions.

12. Method according to claim 10, wherein the method further comprises the following processing steps:
i) deposition of a perforated insulation layer on the metallization side of the solar cell, wherein the insulation layer covers the first and the second contact structures and at least one perforation is located in a region of the first contact structure and at least one second perforation is located in a region of the second contact structure,
ii) deposition of the first and the second connection structures on the insulation layer such that the connection structures penetrate through the insulation layer in the regions of the perforations and border directly on the contacting structures.

13. Method according to claim 10, wherein the method further comprises the following processing steps:
i) generation of recesses in the semiconductor substrate, with the recesses extending through the semiconductor substrate essentially perpendicular to the metallization side,
ii) deposition of the first contact structure,
iii) deposition of a perforated insulation layer on the metallization side of the solar cell, wherein the insulation layer covers the first contact structure and at least one perforation is located in the region of the first contact structure and additional perforations are located in the region of the recesses of the semiconductor substrate,
iv) deposition of the first and the second connection structures on the insulation layer such that the connection structures penetrate through the insulation layer in a region of the perforation, wherein the second connection structure is deposited such that the material of the second connection structure penetrates the perforation of the insulation layer and fills up the recesses of the semiconductor substrate, as well as forms a second contact structure.
